(19) United States
(12) Patent Application Publication
(10) Pub. No.: US 2007/0164417 A1
(43) Pub. Date: Jul. 19, 2007

(54) Design and fabrication method for microsensor

(76) Inventors: Michael A. Todd, Malvern (GB); Carl J. Anthony, Malvern (GB)

Correspondence Address: NIXON & VANDERHYE, PC, 901 NORTH GLEBE ROAD, 11TH FLOOR, ARLINGTON, VA, 22203, US

(21) Appl. No.: 10/589,870

(22) PCT Filed: Feb. 24, 2005
(86) PCT No.: PCT/GB05/00693

§ 371 Date: Aug. 18, 2006

(30) Foreign Application Priority Data
Feb. 27, 2004 (GB) 0404340.2

(51) Int. Cl. H01L 23/02

(52) U.S. Cl. 257/685

(57) ABSTRACT

A method for fabricating a micro-sensor device comprising the steps of fabricating on a parent substrate (10) at least one sensor element (21); forming an interconnect layer (32) having first and second surfaces remotely to the parent substrate (10) so as to enclose the at least one sensor element (21) between the first surface and the parent substrate; providing a plurality of electrical interconnections (33) between the at least one sensor element and a plurality of terminations at the second surface of the interconnect layer, said terminations adapted to interface with a readout substrate. The method may comprise the further step of providing a readout substrate (38) having a plurality of input connections (40) disposed on a first surface thereof, said input connections (40) arranged so as to substantially correspond with the terminations at the second surface of the interconnect layer, and interfacing the plurality of terminations with the corresponding input connections to form an integrated assembly.

The present invention relates to a design for a micro-sensor device and to a method for fabricating the same. Such a design and method may be used in thermal detector arrays such as resistance bolometer arrays and ferroelectric detector arrays.

Micro-sensors typically comprise sensors elements integrated with electronics within a single device using microfabrication technology. While the electronics are fabricated using integrated circuit (IC) process sequences (e.g. CMOS, Bipolar, or BICMOS processes), the micro-sensor mechanical components are typically fabricated using “micromachining” processes that selectively remove or add new structural layers to form the mechanical and electromechanical components within the micro-sensor device.

Bolometer detector arrays are a good example of the successful application of micro-sensor technology. Bolometer detector arrays are used in thermal detection and imaging applications such as surveillance sights, fire-fighting cameras and automobile night driving aids.

With regard to the specific processing techniques used to produce such bolometer detector arrays, there are currently three basic methods used to fabricate these, micro-sensor devices.

Arguably the simplest technique for manufacturing bolometer detectors consists of fabricating the bolometer detector array directly on a silicon readout integrated circuit (ROIC)—usually with a plurality of detector array die on a wafer. Devices produced by this technique are generally referred to as integrated or monolithic arrays. This technique is ideally suited to low-cost applications since the arrays can be fabricated in similar processes used for the fabrication of the ROIC wafers themselves.

The drawbacks to this method are thermal limitations during processing due to the fact that the ROIC cannot be taken above around 500° C. and the fact that the detector material must be grown on a wafer with multiple under-layers on a ROIC substrate. Both of these facts may limit the choice of detector material and may limit the performance of the material and consequently the performance achievable with the thermal imaging system.

An alternative technique for manufacturing bolometer detectors consists of fabricating the detector array bolometers on a separate support silicon wafer. The silicon wafer having the detector array bolometers formed thereon is combined together with the ROIC in a flip-chip bonding process to form what is known as a composite array. In order to achieve electrical continuity the support wafer must be prepared with conducting through-wafer-vias (TWVs). This technique is the subject of an international patent application, publication number WO 98/54554.

The advantage of this alternative technique is that the detector material growth is unconstrained by the ROIC and can, for example, be processed up to temperatures of 900° C. However, this alternative technique does suffer from several disadvantages due to the TWVs in the support wafer. Firstly, the step of incorporating the TWVs in the relatively thick (˜400 μm) support wafer is not trivial. Standard semiconductor processing techniques are not suited to producing the TWVs; the fabrication process is long and complex (and hence expensive). Furthermore, the fact that the TWVs occupy a relatively large proportion of the surface area of the support silicon wafer limits the size and pitch of the detector elements in the array. Hence, the fill-factor of the array is reduced and it may be difficult to use this technique for small pitch arrays.

In common with the above method, a further alternative technique for manufacturing thermal detectors also consists of growing the detector material on a separate silicon wafer. However, in contrast to the foregoing method, the support wafer is then inverted and secured to the ROIC wafer using a gluing process. The first silicon wafer is later removed and further processing is carried our to fabricate the thermal detector structures and form connections to the ROIC through the glue layer. This again has the advantage of de-coupling the detector material growth from the ROIC and should be suitable for small-pitch arrays, however the transfer process is technically difficult for full-size wafers. The fill-factor within the array may also be compromised since this technique precludes abutment of detector elements within the array (spaces must be allowed at the edges of the detector elements in order to facilitate connection of the elements to the ROIC).

This technique is the subject of U.S. Pat. No. 6,287,940 which describes a dual wafer attachment process. In U.S. Pat. No. 6,287,940 a support wafer, having a microstructure fabricated thereon, and an ROIC wafer are both coated in a soft-baked polyimide which acts as a thermoplastic glue layer. The application of heat and pressure to the wafers causes a bond to be formed between the two coatings of polyimide. In this particular example, the polyimide layer is a sacrificial layer which is subsequently removed from the device so as provide thermal isolation between the microstructure and the ROIC.

The foregoing fabrication techniques go some way towards solving the problem of the potentially incompatible production techniques used respectively to manufacture micro-sensor structures (specifically bolometer detectors) and ROICs. However there is scope to improve the overall performance of electronic devices incorporating micro-sensors through the use of sensor materials with improved functional performance and/or through improved microstructure design.

Improved sensor material properties can come for example through the use of single crystalline sensor materials rather than polycrystalline or amorphous materials. Often these improved sensor materials require specialised processing, for example high growth temperatures and/or lattice-matched substrates. To integrate these materials in a micro-sensor device therefore requires specialised fabrication techniques.

It is an object of the present invention to provide an alternative design for a micro-sensor device and a method for fabricating the same. It is a further object of the present invention to provide a micro-sensor device in which the sensor material properties and/or performance of the micro-sensor structures are improved.

According to a first aspect of the present invention there is now proposed a method for fabricating a micro-sensor device comprising the steps of
(i) fabricating on a parent substrate at least one sensor element,
(ii) forming an interconnect layer having first and second surfaces remotely to the parent substrate so as to enclose the at least one sensor element between the first surface and the parent substrate,
(iii) providing a plurality of electrical interconnections between the at least one sensor element and a plurality of terminations at the second surface of the interconnect layer, said terminations adapted to interface with a readout substrate,
(iv) providing a readout substrate having a plurality of input connections disposed on a first surface thereof, said input connections arranged so as to substantially correspond with the terminations at the second surface of the interconnect layer,
(v) interfacing the plurality of terminations with the corresponding input connections to form an integrated assembly.
(vi) removing the parent substrate from the integrated assembly within an area corresponding substantially with the at least one sensor element.

Conveniently, the plurality of terminations are arranged on the second surface of the interconnect layer.

Advantageously, the step of providing the plurality of electrical interconnections between the at least one sensor element and the plurality of terminations at or on the second surface of the interconnect layer is performed before the step of integrating the parent substrate having the at least on sensor element thereon with the readout substrate.

In a preferred embodiment, the plurality of electrical interconnections are arranged within an area of the interconnect layer corresponding substantially with an area defined by the at least one sensor element and being arranged substantially there-under.

In another preferred embodiment, the plurality of terminations at or on the second surface of the interconnect layer are arranged within an area thereof corresponding substantially with the area defined by the at least one sensor element and being arranged substantially there-under.

The foregoing method is advantageous in that the electrical interconnections to the at least one sensor element are arranged at the interconnect layer rather than the parent substrate. This facilitates a high fill factor where a plurality of sensor elements are used, for example in a close-packed array, since the electrical interconnections through the interconnect layer and the terminations at or on the second surface thereof may be arranged underneath the sensor elements. Moreover, in the case where interconnections comprise vias, the process of forming a via in the interconnect layer is less complex than forming a via in the parent substrate. The step of removing the parent substrate from the integrated assembly allows for further processing to be applied to the sensor element and allows the sensor element to be exposed to the medium to be sensed.

Advantageously, the step of interfacing the terminations with the corresponding input connections comprises the step of forming metal connection bonds there-between. The metal connection bonds may comprise Indium metal connection bonds. Conveniently, the readout substrate comprises an integrated circuit.

The use of Indium metal connection bonds (also known as “bump-bonds”) enables the connection bonds which connect the interconnect layer and the readout substrate to be arranged underneath each of the sensor elements rather than at the edges of each sensor element. The sensor elements may thus be arranged in an array having a high fill factor.

In a preferred embodiment, the step of fabricating the at least one sensor element comprises the step of forming the at least sensor element on the parent substrate so as to impart a crystallographic relationship there-between. In particular, the step of fabricating the at least one sensor element may comprises an epitaxial process such that the crystallographic structure of the parent substrate is imparted to the at least one sensor element during said process.

Advantageously, the parent substrate exhibits a substantially single-crystal structure. The use of a substantially single-crystal substrate in the foregoing method enables substantially single-crystal sensor elements. The single-crystal structure enhances the performance of the sensor elements over sensors having a polycrystalline or amorphous structure.

Conveniently, the step of fabricating the at least one sensor element comprises a heat treatment step. The heat treatment step improves the material properties of the sensor elements, thereby enhancing the performance of the sensor elements.

In a preferred embodiment, the heat treatment step is carried out at a temperature of at least 500° C. Preferably, the heat treatment step is carried out at a temperature of at least 800° C. The heat treatment step may be carried out at a temperature of at least 1000° C.

The step of fabricating the at least one sensor element may comprise the step of depositing onto the parent substrate one of a resistive thin-film layer and a ferroelectric thin-film layer. For example the resistive thin-film layer may comprise a multi-component conducting oxide colossal magnetoresitive material. By way of further examples the resistive thin-film layer may comprise Lanthanum Barium Manganite (LBMO) or Lanthanum Calcium Manganite (LCMO). The ferroelectric thin-film layer may comprise a multi-component ferroelectric oxide such as Lead Scandium Tantalate (PST).

The method may comprise the intermediate step of depositing a buffer layer onto the parent substrate prior to the deposition of the thin-film sensor layer. The buffer layer may comprise at least one of Strontium Titanate, Yttria-stabilised Zirconia, Cerium Oxide, Bismuth Titanate and Lanthanum Nickelate.

The deposition of one or both of the sensor layer and the buffer layer may involve a heat treatment step. This heat treatment may be during or after the deposition process.

The step of substantially removing the parent substrate may comprise etching the parent substrate using Tetramethyl Ammonium Hydroxide (TMAH). Advantageously, the Tetramethyl Ammonium Hydroxide etchant is doped with at least one of Silicon and Diammonium Peroxydisulphate. Further processing steps may be carried out after the removal of the parent substrate. For example, one such further processing step in the fabrication of a micro-sensor device may comprise the step of removing sacrificial layers from beneath the sensing element(s).

The Silicon dopant incorporated into the TMAH prevents the etchant from attacking any aluminium which may be exposed on the readout substrate. The Diammonium Peroxydisulphate dopant is beneficial in that it increases the etch rate during the etching process.

According to a second aspect of the present invention, there is now proposed a micro-sensor device comprising, at least one sensor element; an interconnect layer having a first surface facing towards the at least one sensor element and a second surface facing away from the at least one sensor element, said interconnect layer having a plurality of electrical interconnections between the at least one sensor element and a plurality of terminations at the second surface of the interconnect layer; and processing means disposed adjacent the second surface of the interconnect layer, said processing means having a plurality of input connections corresponding substantially with the plurality of terminations and interfaced therewith.

Typically, the interconnect layer and the processing means are fabricated independently of one another and subsequently interfaced together. The interface between the terminations at the second surface of the interconnect layer and the corresponding input connections at the processing means preferably comprise a plurality of connection bonds there-between. The connection bonds may comprise metal connection bonds, for example Indium bonds.

In a preferred embodiment the micro-sensor device comprises an array having a plurality of thermal detector sensor elements. The thermal detector sensor elements may comprise at least one micro-bridge sensor element.

Advantageously, the sensor elements comprise one of a ferroelectric material and a resistive material having a temperature-dependant resistivity. The resistive thin-film layer may comprise a multi-component conducting oxide, for example a colossal magnetoresitive material. By way of further examples the resistive thin-film layer may comprise Lanthanum Barium Manganite (LBMO) or Lanthanum Calcium Manganite (LCMO). The ferroelectric thin-film layer may comprise a multi-component ferroelectric oxide such as Lead Scandium Tantalate (PST).

Conveniently, the at least one sensor element exhibits a substantially single-crystal structure. The single-crystal structure enhances the performance of the sensor elements over sensors having a polycrystalline or amorphous structure.

Preferably, the interconnect layer is electrically non-conductive. This is particularly advantageous where the interconnections between the at least one sensor element and the plurality of terminations at the second surface of the interconnect layer are achieved using vias passing through said interconnect layer. Accordingly, the individual interconnections are inherently electrically isolated from one another.

The interconnect layer may be substantially amorphous or polycrystalline. The interconnect layer may comprise a dielectric material, for example silicon nitride. In a preferred embodiment the interconnect layer has a thickness of less than 100 μm.

Preferably, the interconnect layer has a thickness of less than 10 μm.

Even more preferably, the interconnect layer has a thickness of less than 5 μm.

Advantageously, the at least one sensor element is thermally isolated from the interconnect layer, for example by an intervening cavity or gap. Consequently, the interconnect layer can be relatively thick, for example having a thickness of at least 1 μm, 1.2 μm, 1.4 μm, 1.6 μm, 1.8 μm etc.

Arranging the interconnect layer as a thin-film layer having a thickness as described above facilitates the fabrication of vias through the interconnect layer.

According to a third aspect of the present invention there is now proposed a radiation detector having a micro-sensor device according to the second aspect of the present invention.

The invention will now be described, by example only, with reference to the accompanying drawings in which;

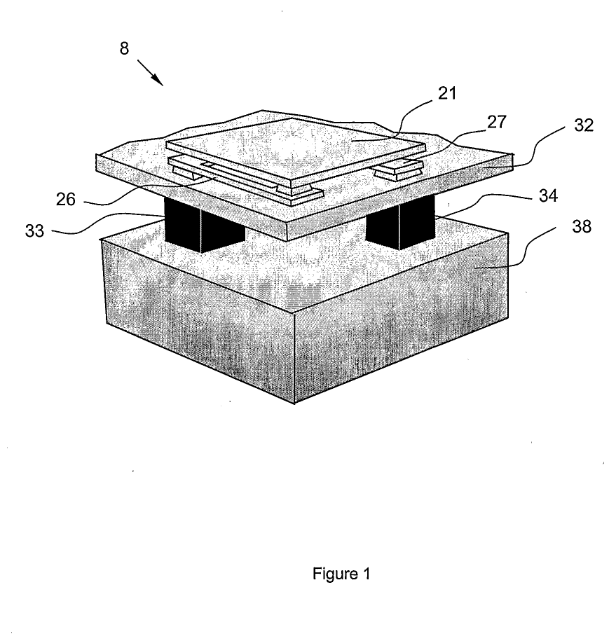

FIG. 1 shows a three-dimensional schematic representation of a radiation detector device according to a first embodiment of the present invention. The figure shows a single sensor element within the radiation detector device.

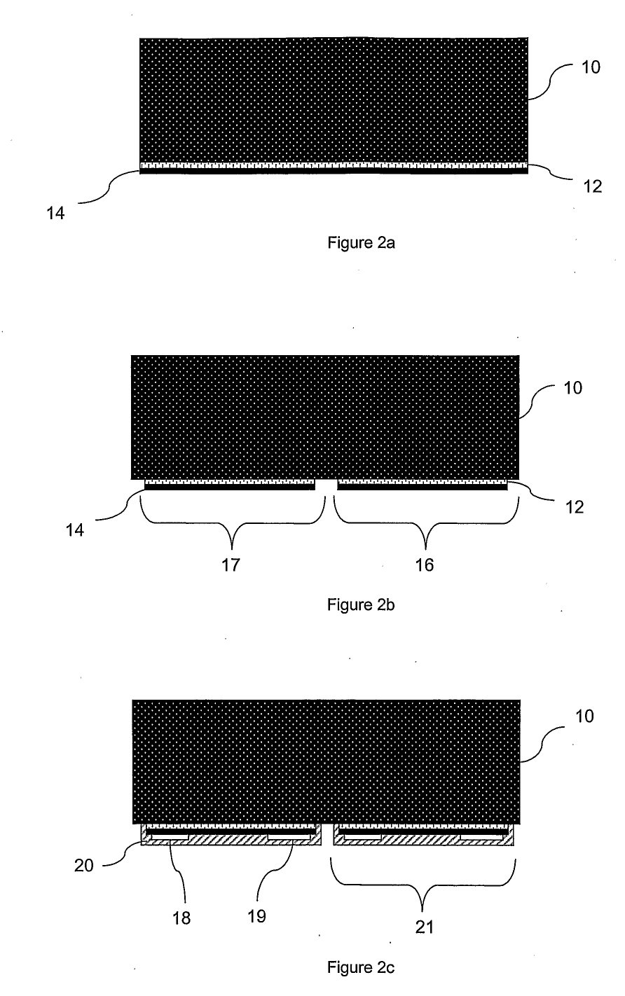

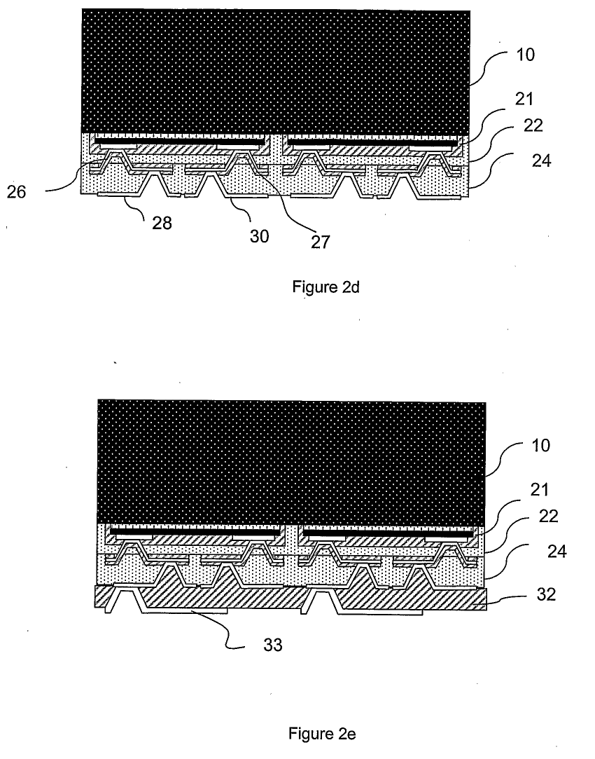

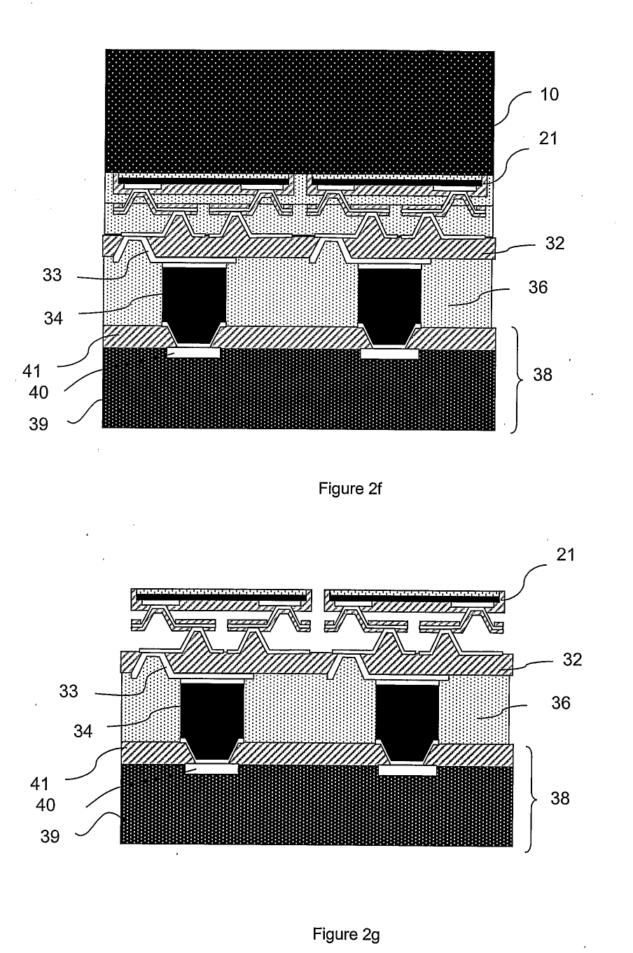

FIGS. 2a-2g show cross-sectional schematic views through a micro-sensor bolometer radiation detector device of the type shown in FIG. 1 during fabrication and illustrate the sequential steps of the fabrication process according to one embodiment of the present invention. The figures show two sensor elements within the bolometer radiation detector device.

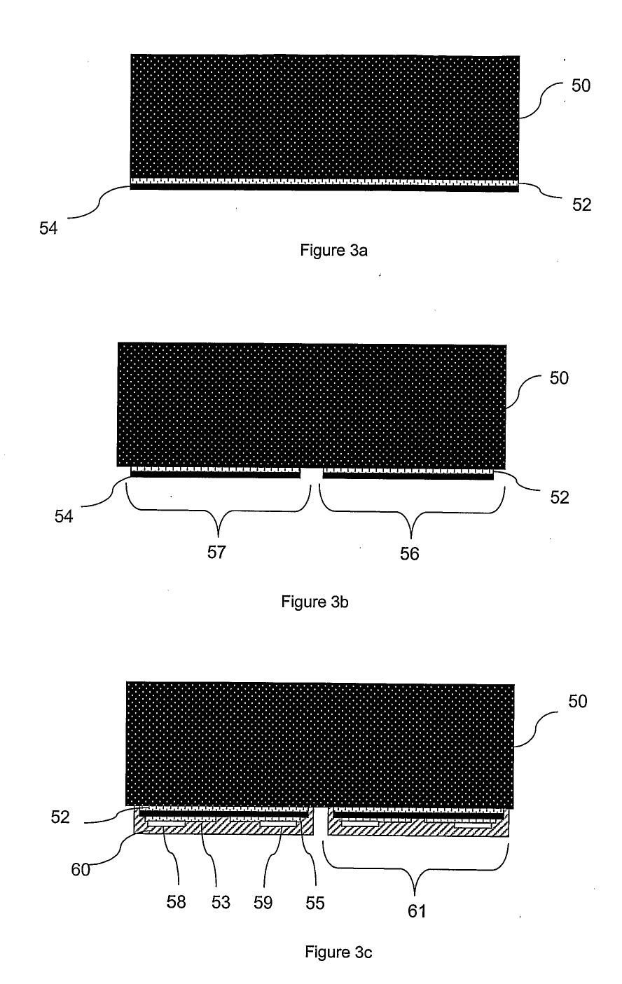

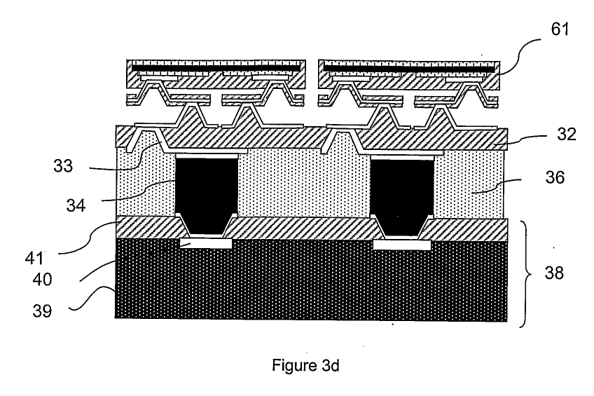

FIGS. 3a-3d show cross-sectional schematic views through a ferroelectric radiation detector device of the type shown in FIG. 1 during fabrication and illustrate the sequential steps of the fabrication process according to a further embodiment of the present invention. The figures show two sensor elements within the bolometer radiation detector device.

One embodiment of the invention is a radiation detector device that may consist of a single sensor pixel, or a linear array of more than one pixel, or a two-dimensional array of sensor pixels. In the radiation detection device, a first part is electrically connected to a second part using metallic bump-bonds. The first part comprises a planar sensor element supported in spaced relation over a planar interconnect membrane layer using support members. Typically, the sensor element contains a thin-film thermal detector sensor layer that has been processed at high temperature i.e. over 500° C. The support members are arranged to offer a degree of thermal isolation between the sensor element and the interconnect membrane layer. The second part comprises a planar readout substrate layer that contains electrical circuitry to drive, and read-out, signals from the sensor element. In operation, electromagnetic radiation incident on the device is absorbed by the sensor element and causes a temperature change of the thermal detector sensor layer. This temperature change gives rise to a change in an electrical property that can be sensed using electronic circuits on the readout substrate layer and used to indicate the amount of incident radiation. The thermal detector sensor thin-film layer may have a temperature-dependant resistivity or have a temperature dependant polarisation, such as observed in ferroelectric layers.

Referring now to the figures, one sensor pixel 8 of a radiation detector device according to a first embodiment of the present invention is shown in FIG. 1. In this device a first part is electrically connected to a second part using metallic bump-bonds 33 & 34.

In this first embodiment of the present invention, the first part comprises a planar sensor element 21, a thin planar interconnect membrane layer 32, and two support members 26 & 27. The planar sensor element 21 is supported in spaced relation over the planar interconnect membrane layer 32 using the support members 26 & 27. The support members 26 & 27 are arranged to offer a degree of thermal isolation between the sensor element layer 21 and the interconnect membrane layer 32. The second part comprises a planar readout substrate layer 38 that contains electrical circuitry to drive and read-out signals from the sensor element 21.

The sensor element 21 contains a thermal detector thin-film layer that has an electrical property that changes with temperature. The support members 26 & 27 contain an electrically conducting layer that carries electrical signals from the thermal detector thin-film layer to the upper surface of the interconnect membrane layer. Electrically conducting tracks (not shown in FIG. 1) are used to carry the electrical signals through vias in the interconnect membrane layer 32 to the lower surface of the interconnect membrane layer and thence to contact the metallic bump-bonds 33 & 34. It is therefore arranged that a continuous electrical circuit is formed from the readout substrate layer through one bump-bond 33 to the thermal detector thin-film layer in the sensor element. The circuit continues back from the thermal detector thin-film layer to the readout substrate layer through a separate bump-bond 34.

The thermal detector thin-film layer in the sensor element 21 may be a thin-film layer with a temperature-dependant resistivity or a thin-film ferroelectric layer with a temperature dependant polarisation.

Whereas the device in FIG. 1 shows a single sensor pixel, a plurality of sensor pixels may be obtained by fabricating a plurality of sensor elements in spaced relation over a single planar interconnect membrane layer, with each sensor element being supported using two support members. In this case a plurality of bump-bonds is used to connect the interconnect layer to a single planar readout substrate layer. It is arranged that each sensor element is connected to circuitry on the readout substrate layer by at least one bump-bond and it may be preferred to use one bump-bond as a ‘common’ electrical contact to several sensor elements.

The following method describes the fabrication of one embodiment of the invention which is a bolometer detector wherein the active layer is a thin-film resistor. This embodiment will be described for the case where the thin-film resistor is a multi-component conducting oxide material that has been processed at high temperatures and has a predominantly single-crystal structure. It will be clear to one skilled in the art that a similar method could be used to fabricate a bolometer detector with other thin-film resistor materials, for example metals or polycrystalline conducting oxides or semiconductor materials, which have a temperature sensitive resistance.

FIGS. 2a-2g show cross-sectional schematic views illustrating successive steps in the fabrication of a resistance bolometer detector of the type shown in FIG. 1 (two sensor elements are shown). The fabrication method is described below with reference to FIG. 2.

Referring to FIG. 2a, to fabricate the first part a thin-film bolometer layer 14 is deposited on a transfer substrate 10 that is preferably single-crystal Silicon but may be another material. The transfer substrate 10 is of sufficient thickness and mechanical strength to support the deposition and processing of multiple thin-film layers used in the fabrication of the first part. Any one of a range of standard thin-film deposition methods may be used to deposit the bolometer thin-film layer, for example chemical vapour deposition, sputtering, pulsed laser deposition, molecular beam deposition, atomic layer deposition or sol-gel deposition. In this embodiment of the invention, the bolometer thin-film layer 14 and the single-crystal transfer substrate 10 are arranged such that there is a structural relationship there between, so that the bolometer thin-film layer forms a predominantly single-crystal structure. In other words there is an epitaxial relationship between the bolometer thin-film layer 14 and the transfer substrate 10. Additional thin-film buffer layers 12 may be used between the transfer substrate 10 and the bolometer thin-film layer 14 to improve the quality of the bolometer thin-film layer. The buffer layer 12 may be a single layer of a single material, or multiple layers of different materials, but there will be an epitaxial relationship between the bolometer thin-film layer 14, the buffer layer or layers 12 and the transfer substrate 10. In one example the bolometer thin-film layer is a multi-component conducting oxide material such as Lanthanum Barium Manganite (LBMO). The preferred deposition method is chemical vapour deposition using liquid precursors, La(thd)₃, Ba(thd)₂, Mn(thd)₃, where thd=2,2, 6,6, tetramethyl heptane 3,5 dionate. LBMO has a close structural relationship to Silicon, however it is known that it is difficult to grow some single-crystal oxide materials, such as LBMO, directly on Silicon due to the formation of amorphous Silicon Oxide at the interface and/or problems due to thermal expansion strain mismatch between Silicon and the single-crystal oxide films. The use of buffer layers to enhance the growth of single-crystal oxide materials on Silicon is also known.

For example multi-layer buffers consisting of Yttria-stabilised Zirconia, Cerium Oxide and Bismuth Titanate have been used as buffer layers for the growth of Lanthanum Strontium Calcium Manganite films on silicon. In an alternative scheme, Strontium Titanate layers have been used as buffer layers for a variety of oxides on silicon. In the preferred fabrication process, LBMO films are deposited on a dual buffer layer consisting of Yttria-stabilised Zirconia and Bismuth Titanate. Preferably these are deposited by Chemical Vapour Deposition. It should be clear to one skilled in the art that other buffer layers and single-crystal oxide material combinations may be used within the scope of this invention. One advantage with the present invention over other known methods is that it is suited to growth of single-crystal thin-film bolometer layers, since the growth of the bolometer thin-film layer and buffer layers is on a plain, unpatterned single-crystal substrate.

Optionally, the bolometer thin-film layer 14, the buffer layer or layers 12 and the transfer substrate 10 are thermally heated in a controlled atmosphere to improve the quality of the bolometer thin-film layer. One advantage of the current invention over other known methods, where thin-film resistors are fabricated over layers containing circuitry, is that the temperatures used during growth and post-growth heating of these layers can be above 500° C., and preferably up to 800° C. or even up to 1000° C.

Referring to FIG. 2b, the bolometer thin-film layer and buffer layers are patterned and etched using standard photolithography and etching methods to form individual resistor elements 16 and 17. The preferred etching process is ion-beam milling. FIGS. 2b-2g show two such elements, however it should be clear that the same method could be used to form a single element or a plurality of elements. In practice, a number of two-dimensional arrays of resistor elements are fabricated on the same transfer substrate. The preferred pitch between resistor elements in a two-dimensional array is 25 μm, although a pitch in the range 15 μm to 100 μm is also possible. The shape of the resistor element is determined by the requirements of the final device, for example the element may be substantially square or may be patterned into a serpentine structure in order to achieve a certain resistance value. The resistor element is substantially square in the embodiment shown in FIG. 2.

Referring to FIG. 2c, metallic contact pads 18 and 19 are deposited and patterned on the bolometer thin-film layer to form electrical contacts. It is convenient to form these using conventional photolithographic float-off techniques. The metallic contact pads are chosen to form an ohmic contact to the bolometer thin-film layer. Typically, the contact pads 18 and 19 are small in lateral dimension compared to the lateral dimension of the resistor elements 16 and 17. In the preferred embodiment the metallic contact pads are Platinum. This is followed by the deposition of a dielectric bridge layer 20. In the preferred embodiment the bolometer thin-film layer 14 is encapsulated by the dielectric bridge layer 20. The preferred material for the dielectric bridge layer is Silicon Nitride, which may be conveniently deposited by Plasma-Enhanced Chemical Vapour Deposition (PECVD). The dielectric bridge layer 20 is patterned and etched over the individual elements 16 and 17 to form individual sensor elements 21. The preferred etching process is reactive-ion etching (RIE).

In order to provide a degree of thermal isolation to improve the response of the bolometer detector device, a cavity, or gap, needs to be formed between the sensor element 21 and any supporting layer with significantly higher thermal mass. It is known that this can be achieved by use of a sacrificial layer, which is used during fabrication of the device, but removed prior to completion of the device. The cavity formed by removal of the sacrificial layer acts as a thermal isolation layer, and this can be further enhanced by packaging the device in a vacuum, so that a vacuum cavity is formed. A double sacrificial layer is used to form the cavity in this embodiment of the present invention. Alternatively, a single sacrificial layer is used.

Referring to FIG. 2d, the first sacrificial layer 22 is deposited over the sensor elements 21. Typically, the first sacrificial layer is a polyimide material, which deposited by spin-deposition and baked. Support members 26 and 27 are used to support the sensor elements and form an electrical connection to the sensor elements. In this embodiment, the support members 26 and 27 consist of a sandwich layer structure of Silicon Nitride, Titanium metal and Silicon Nitride. The support members are fabricated by depositing the first Silicon Nitride layer over the first sacrificial layer 22 and then etching vias, preferably using RIE, through the first Silicon Nitride layer and the first sacrificial layer 22 and the dielectric bridge layer 20 to the contact pads 18 and 19. Titanium metal is then deposited, preferably by sputtering, to make electrical contact to the contact pads 18 and 19. A second Silicon Nitride layer is deposited over the Titanium layer. The sandwich layer structure of Silicon Nitride, Titanium metal and Silicon Nitride is then patterned and etched to form narrow-width support members 26 and 27. The shape and dimensions of the support members 26 and 27 are determined by the level of thermal isolation required i.e. the members may be thin, long and narrow and either straight, ‘L’-shaped, or of a folded, serpentine design to maximise thermal isolation.

A second sacrificial layer 24 is deposited over the first 22 so as to encapsulate the support members 26 and 27. Typically, the second sacrificial layer 24 is also a polyimide material, which is deposited by spin-deposition and baked. To make contact to the support members, vias are etched through the second sacrificial layer and the second Silicon Nitride layer of the support members, preferably using RIE. A metal reflector layer is deposited so as to lie over the second sacrificial layer and to make electrical contact with the Titanium in the support members. This metal reflector layer is patterned and etched to isolate the electrical connections 28 and 30. Preferably the metal reflector layer 28 and 30 is sputtered Titanium. The metal reflector layer can be patterned into tracks to form common electrical connections between a number of sensor elements (typically one connection to each sensor element will be a common connection). A second function of the metal reflector layer is to enhance the radiation absorption of the bolometer device as will be described later. In this case is preferred to maximise the area of metal reflector that is directly underneath the sensor element.

FIG. 2e illustrates the next step of the device fabrication. A dielectric interconnect support layer 32 is deposited over the metal reflector 28 and 30 and second sacrificial layer 24. The interconnect support layer 32 is preferably made of Silicon Nitride deposited by PECVD. Since the interconnect support layer does not form the major part of the thermal isolation of the sensor element, it can be relatively thick compared to the support members. On the other hand, since the fabrication of the first part is supported by the transfer substrate 10, the interconnect support layer can be a thin-film layer. For example in the preferred device design the interconnect support layer is approximately two micrometers thick. This means that small vias in the range of 1 μm to 5 μm diameter can be defined and etched through the interconnect support layer using standard thin-film processing techniques. This is simpler and allows a higher density of pixels compared to existing methods. Vias are etched through the interconnect layer to stop on the metal reflector layer. Metal connection tracks 33 are deposited on top so as to make electrical contact with the metal reflector layer 28. In the preferred device the metal connection tracks 33 are Aluminium, deposited by sputtering. The metal connection tracks are then patterned and etched to form electrically isolated tracks.

Referring to FIG. 2f, the second part of the device is a circuitry component 38. Typically, the circuitry component 38 contains Complementary Metal-Oxide Semiconductor (CMOS) electronic circuits 39 that are designed to provide the required control signals and signal processing to enable the bolometer device to operate as a radiation detector. These circuits will be covered with a passivation layer 41 preferably consisting of Silicon Nitride. Electrical connection to the CMOS circuitry 39 is through metal input pads 40 that connect through vias in the passivation layer 41. For a two-dimensional array of sensor elements it is known how to design CMOS circuits to enable the bolometer device as an imaging radiation detector. For each bolometer thin-film sensor pixel in the first part, there will be a circuitry pixel and at least one input pad in the second part.

A flip-chip bonding method is used to interface the first part with the second part, as shown in FIG. 2f. Flip-chip bonding is a known method of forming high-density interconnects between device components and circuitry. Flip-chip bonding may use heat and/or pressure to form the metal connection bonds. Prior to bonding, bonds may be present on both the device component and the circuitry component, or bonds may be present on only one of the components. Referring to FIG. 2f, Indium metal bonds 34 are deposited and patterned on the first part to form an electrical contact to the metal connection tracks 33. Further Indium metal bonds are deposited and patterned on the second part i.e. the circuitry component 38, to make contact with the metal input pads 40. The bonds on the two components are arranged so that the bonds can be brought in contact when one component is aligned with the other. Thus in the preferred device, one input pad 40 on the CMOS circuitry is electrically connected to one side of each bolometer thin-film layer resistor element 17, through the Indium bond 34, the Aluminium metal connection track 33, the Titanium reflector metal 28, the Titanium support member metal 26 and the Platinum contact pad 18. The return connection from each bolometer thin-film layer resistor element to the CMOS circuitry may be either through a second Indium bond located within the area defined by the sensor element or may be tracked out, using the reflector and/or the metal connection tracks, and connected through a second Indium bond in an area outside the area defined by the sensor element. This return connection may be common between a number of pixels. The return connection to the circuitry component is not shown in FIGS. 2a-2g.

The flip-chip bonding process is carried out with the transfer substrate 10 still in place since this acts as a mechanical support to the thin-film device layers and allows bonding pressure to be applied without damage to the thin-film layers. The advantage of using flip-chip bonding in the present invention over other known CMOS integration methods, such as direct wafer-bonding or gluing, is that the flip-chip bond forms the electrical connection to the CMOS directly under the sensor element. This means that the sensor elements can be closely spaced and the radiation absorbing area can fill a large proportion of the area available for each pixel within an array. In other words the pixel fill-factor can be high using the present invention.

Optionally, an underfill material 36 can be used to encapsulate the flip-chip bonds and provide additional mechanical support to the bonded part. In the present invention an epoxy-based underfill material such as Ablebond® 968-2 is preferred. This is applied to the edge of the bonded chip such that the underfill material fills the gap between the two parts by capillary action.

The next step in the preferred device fabrication is to remove the transfer substrate 10 from the flip-chip bonded part. It is preferred to do this by wet-etching, although a dry etching process may also be used, for example known silicon dry etch processes use Xenon Difluoride or reactive-ion etching using Sulphur Hexafluoride. In the preferred wet-etching process, Tetramethyl Ammonium Hydroxide (TMAH) is used, with the chemical formula (CH₃)₄NOH. TMAH is the main ingredient in many positive photoresist developers and is available in the very clean grades required for semiconductor manufacture. Unlike other etchants such as KOH, TMAH does not contain alkali ions that are detrimental to CMOS circuitry. TMAH is also relatively safe compared to the other Silicon etchants such as Hydrazine and EDP. TMAH can be made so that it does not etch Aluminium, which is important if exposed Aluminium is present on the circuitry component. This is achieved by dissolving Silicon in the TMAH to reduce the pH to a point that silicates in the solution passivate the aluminium surface. For TMAH diluted to ˜5 wt. % then 16 g/L of Si must be dissolved in the solution to prevent aluminium attack. This gives a solution of pH ˜11.5 where the Aluminium is stable. Silicon doping also has the advantage of increasing the selectivity of the etchant to the Silicon Nitride. It has been suggested to add strong oxidisers such as Diammonium Peroxydisulphate (AP) to the etchant to overcome problems of low etch rate due to surface roughness caused by hydrogen bubble generation during the Silicon etch. Thus dual doping of TMAH with Silicon and AP is preferred for the removal of the silicon transfer substrate of this invention. However, since the AP oxidiser slowly gets consumed within the etch solution the etch rate will fall during the etch and impractical etch-times will result. Accordingly, the etch solution is periodically refreshed and the addition of the AP-doped solution is carried out continually at a rate of 1 ml/min. The etch is carried out in a 1 litre quartz flask with a reflux condenser on a hotplate, set such that the liquid is heated to ˜82° C. A flip-chip bonded part, fabricated as described above, is placed on the base of the flask. Slow stirring is carried out with a magnetic stirrer bar. An automated system using three peristaltic pumps with timer controls is employed: one to slowly add the AP-doped solution, one to add fresh Si doped solution and one to remove the spent etch solution. The AP-doped solution is 5 wt. % TMAH with ˜30 g/L AP added and dissolved by stirring. The etch solution is periodically refreshed by pumping out the spent etchant and adding ˜65 ml of fresh Si-doped etchant. This is 5 wt. % TMAH with dissolved Si doping concentration of 16 g/700 ml. The peristaltic pumps pump at a rate of ˜25 ml/min. The addition pump runs for 3 minutes to deposit ˜60˜70 mls of Si doped TMAH. The extraction pump runs for 4 minutes and is designed to remove the sum of the AP and Si doped liquids at the end of 33 minutes etching. The average etch rate achieved for removal of a 525 μm thick Silicon transfer substrate is over 1 μm/minute.

Having removed the transfer substrate 10, access is gained to the sacrificial layers 22 & 24 through gaps between sensor elements 21. The sacrificial layers 22 & 24, are then removed using a dry isotropic etch process. In the preferred process the polyimide sacrificial layers are removed using an oxygen plasma ash process. As shown in FIG. 2g this leaves a gap or cavity between the sensor elements 21 and the interconnect support layer 32. To increase the thermal isolation of the sensor elements 21, it is preferred to package the completed device in a vacuum package.

To operate as an efficient radiation detector the device must absorb radiation of interest to change the temperature of the bolometer thin-film layer within each sensor element. It is preferred that the sensor element is optically absorptive in the wavelength range of interest. This can be achieved by having optical absorption separately or in combination in the buffer layer or layers 12, the bolometer thin-film layer 14 or the dielectric bridge layer 20. In the embodiment described above the majority of the optical absorption will occur in the LBMO bolometer thin-film layer. To enhance the absorption, the reflector layer 28 is provided to reflect radiation transmitted by the sensor layer back to the sensor layer. It is preferred that the gap between the sensor layer 21 and the interconnect support layer 32 forms a resonant optical cavity to enhance the radiation absorption. Thus in the preferred embodiment the sum of sacrificial layer thicknesses is arranged to be approximately λ/4, where λ is the centre wavelength of the radiation of interest.

The following method describes the fabrication of a second embodiment of the invention which is a thermal radiation detector wherein the active layer is a thin-film ferroelectric material. This embodiment will be described for the case where the thin-film ferroelectric is a multi-component ferroelectric oxide material that has been processed at high temperatures and has a predominantly polycrystalline structure.

FIGS. 3a-3d show cross-sectional schematic views illustrating successive steps in the fabrication of two such ferroelectric detector elements of the type shown in FIG. 1 according to the present invention. The fabrication method is described below with reference to FIG. 3.

In FIG. 3a, to fabricate the first part, a thin-film top electrode layer 52 is deposited on a transfer substrate 50 that is preferably single-crystal Silicon but may be another material. It is advantageous that the top electrode layer 52 is not reflective to the optical radiation and it is therefore preferred that this layer is a conductive oxide thin-film such as Lanthanum Nickelate (LNO). The transfer substrate 50 is of sufficient thickness and mechanical strength to support the deposition and processing of multiple thin-film layers used in the fabrication of the first part. This top electrode layer is followed by the deposition of a ferroelectric thin-film layer 54. Any one of a range of standard thin-film deposition methods may be used to deposit the ferroelectric bolometer thin-film layer, for example chemical vapour deposition, sputtering, pulsed laser deposition, molecular beam deposition, atomic layer deposition or sol-gel deposition. In this embodiment the ferroelectric thin-film layer is a multi-component oxide material such as Lead Scandium Tantalate (PST), which is preferably deposited by sputtering. It is known that PST forms a polycrystalline structure when grown on LNO and can be used as a dielectric bolometer when a suitable bias field is applied. It should be clear to one skilled in the art that other conducting electrode layers and ferroelectric oxide material combinations may be used within the scope of this invention.

It may be advantageous to thermally heat the ferroelectric thin-film layer 54, the top electrode layer 52 and the transfer substrate 50 in a controlled atmosphere to improve the quality of the thin-film layer. One advantage of the current invention over other known methods, where thin-film ferroelectric layers are fabricated over layers containing circuitry, is that the temperatures used during growth and post-growth heating of these layers can be above 500° C., and preferably up to 800° C. or even up to 1000° C.

In FIG. 3b, the ferroelectric thin-film layer 54 and top electrode layer 52 are patterned and etched using standard photolithography and etching methods to form individual ferroelectric elements 56 & 57. The preferred etching process is ion-beam milling. FIGS. 3b-3d show two such elements, however it should be clear that the same method could be used to form a single element or a plurality of elements. In practice, a plurality of two-dimensional arrays of ferroelectric elements are fabricated on the same transfer substrate. The preferred pitch between ferroelectric elements in a two-dimensional array is 25 μm, although a pitch in the range 15 μm to 100 μm is also possible. In the embodiment described here, the ferroelectric element is substantially square.

In FIG. 3c, conducting lower electrodes 53 & 55 are deposited and patterned on the ferroelectric layer 54. The lower electrodes 53 & 55 form planar capacitive elements with the conducting top electrode layer 52. To maximise the capacitor area it is preferred that the area of overlap between the top electrode layer and the lower electrodes is maximised, with the constraint that the lower electrodes are electrically isolated from each other. In the preferred embodiment the conducting lower electrodes are metallic Titanium. Metal contact pads 58 & 59 are deposited and patterned on the lower electrodes to form electrical contacts. It is convenient to form these using conventional photolithographic float-off techniques. In the preferred embodiment the contact pads are metallic Platinum. This is followed by the deposition of a dielectric bridge layer 60. In the preferred embodiment the ferroelectric thin-film layer 54 is encapsulated by the dielectric bridge layer 60. The preferred material for the dielectric bridge layer is Silicon Nitride, which may be conveniently deposited by Plasma-Enhanced Chemical Vapour Deposition (PECVD). The dielectric bridge layer 60 is patterned and etched over the individual elements 56 & 57 to form individual sensor elements 61. The preferred etching process is Reactive-ion etching (RIE).

The remaining steps in the fabrication of the ferroelectric device follow the processing sequence described above for the fabrication of the resistive bolometer detector (FIGS. 2d-2g refer). In this case the transfer substrate 50 is removed after bump-bonding in the same way as described for the transfer substrate 10 in the resistive bolometer detector. This results in the thin-film ferroelectric device shown in FIG. 3d. In this preferred device one input pad on the CMOS circuitry 40 is electrically connected to one lower electrode of the ferroelectric layer 53, through the Indium bond 34, the Aluminium metal connection track 33, the Titanium reflector metal 28, the Titanium support member metal 26 and the Platinum contact pad 58. The top electrode 52 acts as a floating electrode, so that each sensor element operates as two back-to-back series capacitors. The return connection from each ferroelectric thin-film layer element to the CMOS circuitry may be either through a second Indium bond located within the area defined by the sensor element or may be tracked out, using the reflector and/or the metal connection tracks, and connected through a second Indium bond in an area outside the area defined by the sensor element. This return connection may be common between several pixels.

To operate as an efficient radiation detector the device must absorb radiation of interest to change the temperature of the sensor thin-film layer within each sensor element. It is preferred that the sensor element is optically absorptive in the wavelength range of interest. This can be achieved by having optical absorption separately or in combination in the top electrode layer 52, the ferroelectric thin-film layer 54, the lower electrodes 53 & 55, or the dielectric bridge layer 60. In the device described above the majority of the optical absorption will occur in either the LNO top electrode layer or the Titanium lower electrode layer. To enhance the absorption, the reflector layer 28 is provided to reflect radiation transmitted by the sensor layer back to the sensor layer. It is preferred that the gap between the sensor layer 21 and the interconnect support layer 32 forms a resonant optical cavity to enhance the radiation absorption. Thus in the preferred embodiment the sum of sacrificial layer thicknesses is arranged to be approximately λ/4, where λ is the centre wavelength of the radiation of interest.

The present invention has been described in the foregoing embodiments with regard to a micro-sensor radiation detector and to a method for producing the same. However, the design and method of the present invention are not limited to radiation detectors but are potentially applicable to a variety of micro-sensors, for example gyroscopes, accelerometers, acoustic sensors (microphones), etc.

1. A method for fabricating a micro-sensor device comprising the steps of
(i) fabricating on a parent substrate at least one sensor element,
(ii) forming an interconnect layer having first and second surfaces remotely to the parent substrate so as to enclose the at least one sensor element between the first surface and the parent substrate,
(iii) providing a plurality of electrical interconnections between the at least one sensor element and a plurality of terminations at the second surface of the interconnect layer, said terminations adapted to interface with a readout substrate,
(iv) providing a readout substrate having a plurality of input connections disposed on a first surface thereof, said input connections arranged so as to substantially correspond with the terminations at the second surface of the interconnect layer,
(v) interfacing the plurality of terminations with the corresponding input connections to form an integrated assembly, and
(vi) removing the parent substrate from the integrated assembly within an area corresponding substantially with the at least one sensor element.

2. A method according to claim 1 wherein the step of interfacing the terminations with the corresponding input connections comprises the step of forming metal connection bonds there-between.

3. (canceled)

4. A method according to claim 1 wherein the readout substrate comprises an integrated circuit.

5. A method according to claim 1 wherein the step of fabricating the at least one sensor element comprises the step of forming the at least one sensor element on the parent substrate so as to impart a crystallographic relationship there-between.

6. A method according to claim 5 wherein the step of fabricating the at least one sensor element comprises an epitaxial process such that the crystallographic structure of the parent substrate is imparted to the at least one sensor element during said process.

7. A method according to claim 6 wherein the parent substrate exhibits a substantially single-crystal structure.

8. A method according to claim 1 wherein the step of fabricating the at least one sensor element comprises a heat treatment step.

9-10. (canceled)

11. A method according to claim 1 wherein the step of fabricating the at least one sensor element comprises the step of depositing onto the parent substrate one of a resistive thin-film layer and a ferroelectric thin-film layer.

12-15. (canceled)

16. A method according to claim 11 comprising the intermediate step of depositing a buffer layer onto the parent substrate prior to the deposition of the thin-film layer.

17. (canceled)

18. A method according to claim 1 wherein the step of removing the parent substrate comprises etching the parent substrate using Tetramethyl Ammonium Hydroxide (TMAH).

19. A method according to claim 18 wherein the Tetramethyl Ammonium Hydroxide etchant is doped with at least one of Silicon and Diammonium Peroxydisulphate.

20. A micro-sensor device comprising, at least one sensor element; an interconnect layer having a first surface facing towards the at least one sensor element and a second surface facing away from the at least one sensor element, said interconnect layer having a plurality of electrical interconnections between the at least one sensor element and a plurality of terminations at the second surface of the interconnect layer; and a processor disposed adjacent the second surface of the interconnect layer, said processor having a plurality of input connections corresponding substantially with the plurality of terminations and interfaced therewith.

21. A micro-sensor device according to claim 20 comprising an array having a plurality of thermal detector sensor elements.

22. A micro-sensor device according to claim 21 wherein the thermal detector sensor elements comprise at least one micro-bridge sensor element.

23. A micro-sensor device according to claim 20 wherein the sensor elements comprise one of a ferroelectric material and a resistive material having a temperature-dependant resistivity.

24-27. (canceled)

28. A micro-sensor device according to claim 20 wherein the at least one sensor element exhibits a substantially single-crystal structure.

29. A micro-sensor device according to claim 20 wherein the interconnect layer is electrically non-conductive.

30-32. (canceled)

33. A micro-sensor device according to claim 20 wherein the interconnect layer has a thickness of less than 100 μm.

34. A micro-sensor device according to claim 33 wherein the interconnect layer has a thickness of less than 10 μm.

35. A micro-sensor device according to claim 34 wherein the interconnect layer has a thickness of less than 5 μm.

36. A radiation detector having a micro-sensor device according to claim 20.
